(19) United States
(12) Patent Application Publication
(10) Pub. No.: US 2006/0219286 A1
(43) Pub. Date: Oct. 5, 2006

(54) Thermoelectric transducer and manufacturing method for the same

(75) Inventors: Isao Kuroyanagi, Anjo-city (JP); Akio Matsuoka, Takahama-city (JP); Takashi Yamamoto, Okazaki-city (JP); Makoto Uto, Ichinomiya-city (JP); Yukinori Hatano, Okazaki-city (JP); Hirokazu Yoshino, Okazaki-city (JP); Fumiaki Nakamura, Kariya-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/396,128

(22) Filed: Mar. 31, 2006

(30) Foreign Application Priority Data
Apr. 1, 2005 (JP) 2005-106853

(51) Int. Cl. H01L 35/02

(52) U.S. Cl. 136/230

(57) ABSTRACT

A thermoelectric transducer includes a thermoelectric device assembly and a pair of heat exchanging member assemblies arranged at both sides of the thermoelectric device assembly. The thermoelectric device assembly includes a plurality of P-type thermoelectric devices, a plurality of N-type thermoelectric devices, a first holding plate for holding the thermoelectric devices, and a plurality of electrode members for electrically connecting the thermoelectric devices. Each of the heat exchanging member assemblies includes a plurality of heat exchanging members provided in correspondence with the plurality of electrode members, and a second holding plate located for holding the plurality of heat exchanging members. Each of the plurality of electrode members has an outer periphery that contacts one surface of the second holding plate in a state where the electrode member is connected to the heat exchanging member.

### CROSS REFERENCE TO RELATED APPLICATION

This application is based on Japanese Patent Application No. 2005-106853 filed on Apr. 1, 2005, the contents of which are incorporated herein by reference in its entirety.

### BACKGROUND OF THE INVENTION

1. Field of the Invention

The present invention relates to a thermoelectric transducer that has a series circuit including N-type thermoelectric devices and P-type thermoelectric devices and absorbs or radiates heat when a DC current is passed through the series circuit. The present invention further relates to a method for manufacturing a thermoelectric transducer

2. Description of the Related Art

As one of conventional thermoelectric transducers, there is proposed a thermoelectric transducer that has N-type thermoelectric devices and P-type thermoelectric devices alternately arranged in the shape of a plane. In this thermoelectric transducer, the respective thermoelectric devices have one-side electrode members mounted on their one-side surfaces and have other-side electrode members mounted on their other-side surfaces, thereby all thermoelectric devices are connected to each other in series (refer to JP-A-2003-124531 corresponding to U.S. Pat. No. 6,815,814).

In the thermoelectric devices of this type, heat exchanging members for absorbing or radiating heat transmitted from the one-side electrode members and the other-side electrode members are integral with the one-side electrode members and the other-side electrode members. Furthermore, adjacent thermoelectric devices are arranged to be electrically insulated from each other. Accordingly, it is difficult to accurately arrange the thermoelectric devices each having a small size, and the electrode members, thereby assembling steps for manufacturing the thermoelectric transducer are increased.

### SUMMARY OF THE INVENTION

In view of the foregoing problems, it is an object of the present invention to provide a thermoelectric transducer in which a plurality of heat exchanging members can be easily accurately arranged at predetermined positions corresponding to arrangement of a plurality of electrode members of a thermoelectric device assembly.

It is another object of the present invention to provide a method for manufacturing a thermoelectric transducer.

According to an aspect of the present invention, a thermoelectric transducer includes a thermoelectric device assembly and a pair of heat exchanging member assembly arranged at two sides of the thermoelectric device assembly. The thermoelectric device assembly includes a plurality of P-type thermoelectric devices, a plurality of N-type thermoelectric devices, a first holding plate for holding the plurality of P-type thermoelectric devices and N-type thermoelectric devices, and a plurality of electrode members for electrically connecting the plurality of P-type thermoelectric devices and N-type thermoelectric devices in series. Here, the plurality of electrode members are arranged in a predetermined arrangement corresponding to an arrangement of the plurality of P-type thermoelectric devices and N-type thermoelectric devices. In addition, each of the heat exchanging member assemblies includes a plurality of heat exchanging members provided in correspondence with the plurality of electrode members, and a second holding plate for holding the plurality of heat exchanging members. The plurality of heat exchanging members are held in an arrangement corresponding to the predetermined arrangement of the electrode members.

In the thermoelectric transducer, each of the plurality of electrode members has an outer periphery that contacts one surface of the second holding plate in a state where the electrode member is connected to the heat exchanging member. Therefore, the heat exchanging members and the electrode members can be accurately bonded with each other without a position shift of the electrode members that are arranged to correspond to the arrangement of the thermoelectric devices.

Generally, the heat exchanging members have electrode portions connectable respectively to the electrode members of the thermoelectric device assembly to transmit heat, and heat exchanging portions for exchanging heat transmitted from the electrode portions. In this case, the second holding plate has a plurality of insertion holes into which the electrode portions of the heat exchanging members are inserted, respectively. Therefore, the heat exchanging members can be easily temporarily fixed using the second holding plate.

For example, each of the insertion holes of the second holding plate has an open area that is smaller than a surface area of each electrode member connected to the electrode portion of each heat exchanging member. Furthermore, the electrode portion of each heat exchanging member can be press-inserted into the insertion hole of the second holding plate or can be fitted with the insertion hole of the second holding plate. Accordingly, the electrode members of the thermoelectric device assembly can be connected to the electrode portions of the heat exchanging members in a state where the outer periphery of each electrode member contacts the one surface of the second holding plate at a peripheral portion of the insertion hole.

Furthermore, the second holding plate can be located adjacent to connection positions where the electrode members are connected to the thermoelectric devices, and the second holding plate can be separate from the first holding plate by a space.

According to another aspect of the present invention, a method of manufacturing a thermoelectric transducer includes: a step of forming a plurality of P-type thermoelectric devices and a plurality of N-type thermoelectric devices; a step of arranging the plurality of P-type thermoelectric devices and the plurality of N-type thermoelectric devices in a predetermined arrangement to be held by a first holding plate; a step of electrically connecting the plurality of P-type thermoelectric devices and plurality of N-type thermoelectric devices in series by using a plurality of electrode members so as to form a thermoelectric device assembly; a step of forming a plurality of heat exchanging members; a step of holding the plurality of heat exchanging members by using a second holding plate in an arrangement corresponding to a predetermined arrangement of the electrode members so as to form a heat exchanging member assembly; a step of temporarily fixing the thermoelectric device assembly between a pair of heat exchanging member assemblies such that an outer periphery of each electrode member contacts one surface of the second holding plate; and a step of bonding together the electrode members to the respective heat exchanging members in a contact state where the outer periphery of each electrode member contacts the one surface of the second holding plate. Accordingly, the electrode members of the thermoelectric device assembly are not shifted before the heat exchanging members are bonded to the electrode members of the thermoelectric device assembly.

In the step of forming the plurality of heat exchanging members, each of the heat exchanging members can be formed to have an electrode portion connectable to the electrode member and a heat exchanging portion for exchanging heat transmitted from the electrode portion. Further, a plurality of insertion holes can be formed in the second holding plate at positions corresponding to the arrangement of the electrode members such that each of the insertion holes has an open area that is smaller than a surface area of each electrode members. Therefore, the electrode portions of the heat exchanging members can be inserted into the insertion holes of the second holding plate to be temporarily fixed while the electrode members are made contact the one surface of the second holding plate.

### BRIEF DESCRIPTION OF THE DRAWINGS

The above and other objects, features and advantages of the present invention will become more apparent from the following detailed description of preferred embodiments made with reference to the accompanying drawings, in which:

FIG. 1 is a top view showing a part of a thermoelectric transducer in an embodiment of the present invention;

FIG. 2 is a bottom view showing a part of the thermoelectric transducer in the embodiment;

FIG. 3 is a sectional view taken on the line III-III shown in FIG. 1;

FIG. 4 is a schematic sectional view taken on the line IV-IV shown in FIG. 3;

FIG. 5 is a schematic sectional view taken on the line V-V shown in FIG. 3;

FIG. 6 is a disassembled schematic view showing a structure of the thermoelectric transducer in the embodiment of the present invention;

FIG. 7A is a schematic front view showing a shape of a heat exchanging member in this embodiment, FIG. 7B is a side view showing the heat exchanging member, and FIG. 7C is a cross-sectional view taken along the line VIIC-VIIC of FIG. 7A; and

FIG. 8 is a side view showing a heat exchanging member according to a modification of the present invention.

### DETAILED DESCRIPTION OF THE PREFERRED EMBODIMENTS

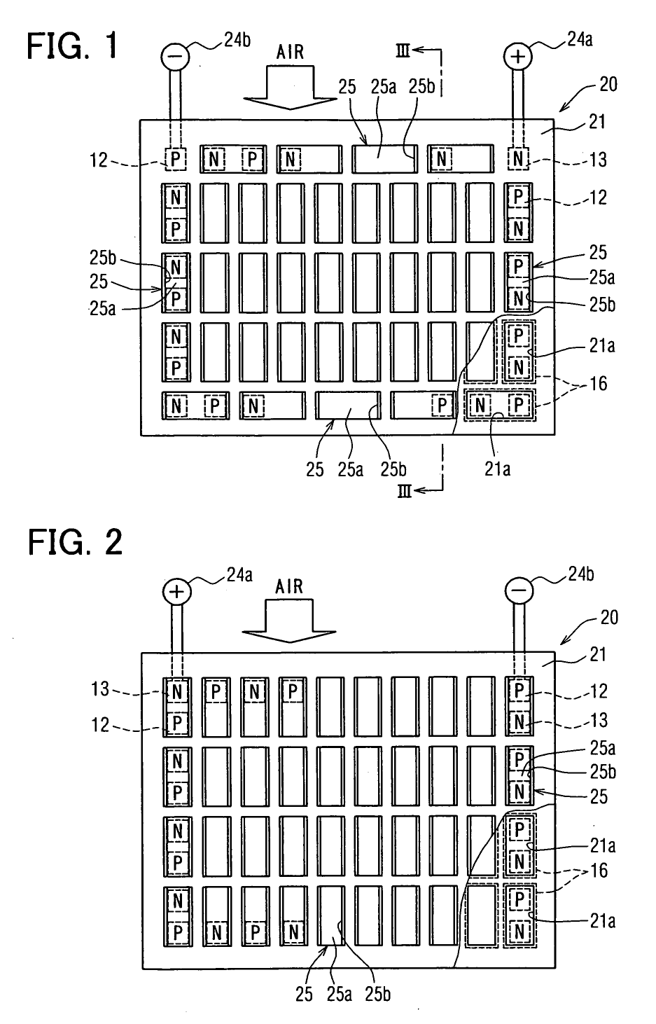

An embodiment of the present invention will be described with reference to FIGS. 1-7C.

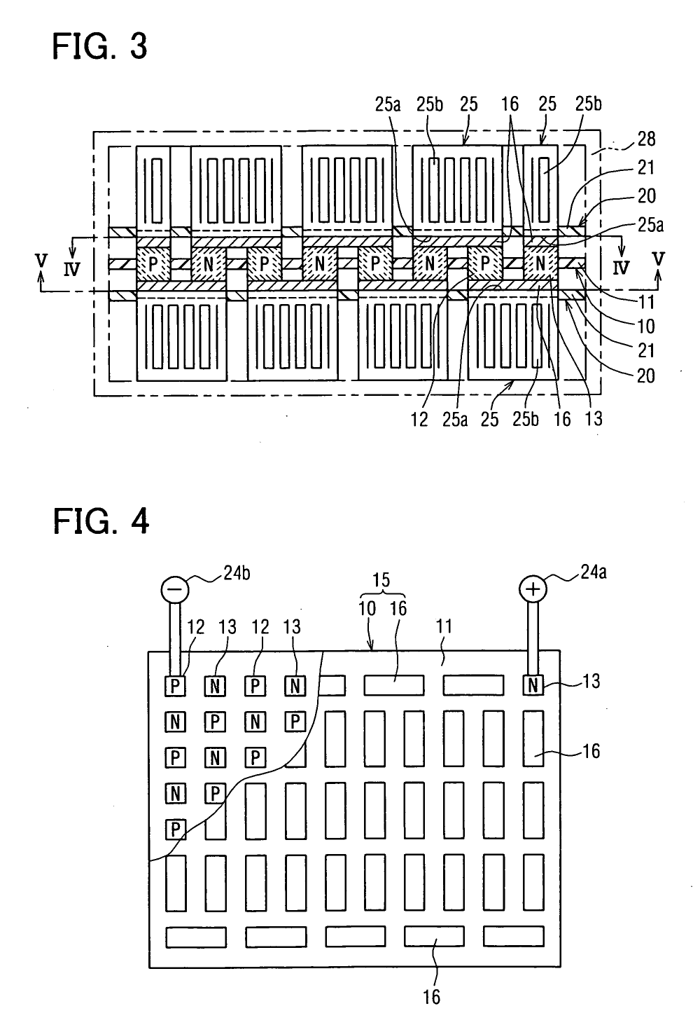

FIGS. 1 and 2 are top view and bottom view showing a thermoelectric transducer according to this embodiment. The thermoelectric transducer of this embodiment, as shown in FIG. 3 and FIG. 4, is constructed with: a thermoelectric device substrate 10 with a plurality of P-type thermoelectric devices 12 and a plurality of N-type thermoelectric devices 13 set in an array; electrode members 16 each of which electrically connects the P-type thermoelectric device 12 with N-type thermoelectric devices 13, which are adjacent to each other, in series; a pair of heat absorbing/radiating substrates 20 each of which has a plurality of heat exchanging members 25 bonded to the electrode members 16 in such a way as to transmit heat; and a pair of case members 28.

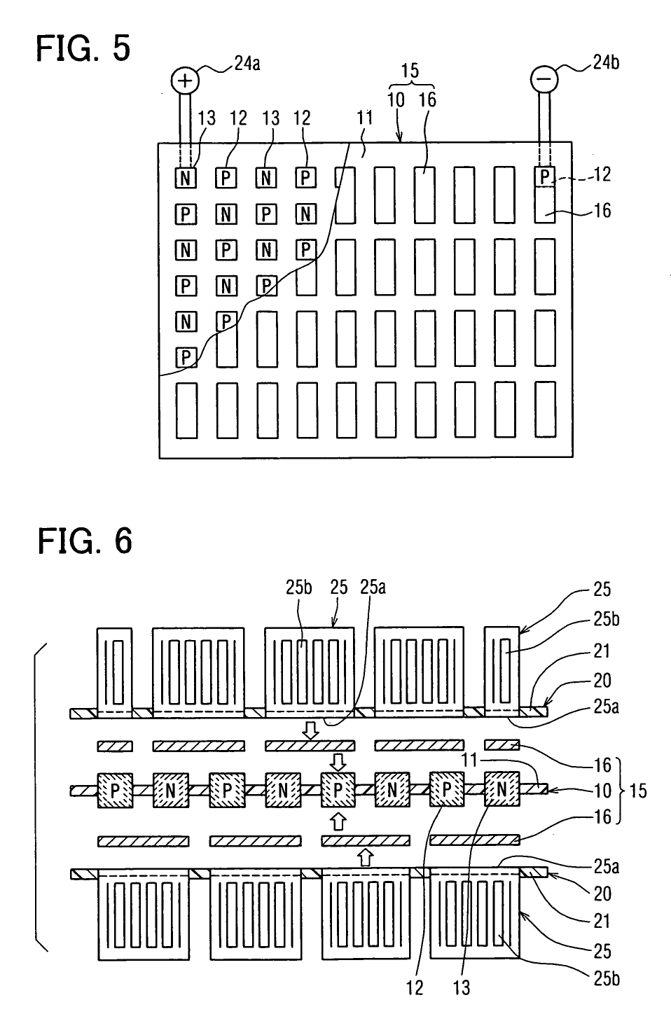

The thermoelectric device substrate 10, as shown in FIG. 4 and FIG. 5, is a thermoelectric device assembly that is integrally constructed of: a first holding plate 11 made of a plate-shaped insulating material (for example, glass epoxy, PPS resin, LCP resin, or PET resin); and a group of thermoelectric devices formed of the plurality of P-type thermoelectric devices 12 and the plurality of N-type thermoelectric devices 13 alternately arranged on the first holding plate 11.

The P-type thermoelectric device 12 is an extremely small component constructed of a P-type semiconductor made of a Bi—Te based compound, and the N-type thermoelectric device 13 is an extremely small component constructed of an N-type semiconductor made of the Bi—Te based compound. The thermoelectric device substrate 10 is integrally formed in such a way that the P-type thermoelectric devices 12 and the N-type thermoelectric devices 13 are arranged on the first holding plate 11 in a lattice pattern. At this time, the P-type thermoelectric devices 12 and the N-type thermoelectric devices 13 are formed in such a way as to protrude their top end surfaces and bottom surfaces from the first holding plate 11.

The thermoelectric devices 12, 13 arranged on a left upper end and a right upper end in the drawing have terminals 24a and 24b, respectively. A positive terminal and a negative terminal of a DC power source (not shown) are connected to these terminals 24a and 24b, respectively.

The electrode member 16 is an electrode that is formed of plate-shaped conductive metal such as copper and electrically directly connects the P-type thermoelectric device 12 with the N-type thermoelectric device 13, which are adjacent to each other, among the group of thermoelectric devices 12, 13 arranged on the thermoelectric device substrate 10. All of the electrode members 16, as shown in FIG. 4 and FIG. 5, are formed in a unified same rectangular shape to cover the end surfaces of the adjacent thermoelectric devices 12, 13.

The electrode members 16 are arranged at specified positions corresponding to the state of arrangement of the thermoelectric devices 12, 13 arranged on the thermoelectric device substrate 10, and are bonded to the thermoelectric devices 12, 13. In other words, a plurality of electrode members 16 are arranged on both end surfaces of the adjacent thermoelectric devices 12, 13.

More specifically, the adjacent thermoelectric devices 12, 13 are connected to each other in such a way as to form an electrical PN junction (which will be described later) on one surface side (refer to FIG. 4) of the thermoelectric device substrate 10 and to form an electrical NP junction (which will be described later) on the other surface side (refer to FIG. 5). The electrode members 16 are soldered to the end surfaces of the thermoelectric devices 12, 13, respectively.

The electrode members 16 arranged on one surface side (refer to FIG. 4) of the thermoelectric device substrate 10 are different in the direction of arrangement between a case where the electrode members 16 are arranged on the thermoelectric devices 12, 13 adjacent to the outside end of the group of thermoelectric devices and a case where the electrode members 16 are arranged on the thermoelectric devices 12, 13 adjacent to the inside of the outside end of the group of thermoelectric devices.

As shown in FIG. 4, when the electrode members 16 are arranged on the thermoelectric devices 12, 13 adjacent to the outside end of the group of thermoelectric devices, the electrode members 16 are arranged in a direction perpendicular to the group of thermoelectric devices, whereas when the electrode members 16 are arranged on the thermoelectric devices 12, 13 adjacent to the inside of the outside end of the group of thermoelectric devices, the electrode members 16 are arranged in a direction along the group of thermoelectric devices. Here, an assembly state where the plurality of electrode members 16 are arranged on and bonded to the thermoelectric device substrate 10 is referred to as “electrode device assembly 15” as shown in FIGS. 4 and 5.

The heat absorbing/radiating substrate 20 of the heat exchanging member assembly, as shown in FIG. 3 and FIG. 6, is integrally constructed of a second holding plate 21 made of a plate-shaped insulating material (for example, glass epoxy, PPS resin, LCP resin, or PET resin) and a plurality of heat exchanging members 25.

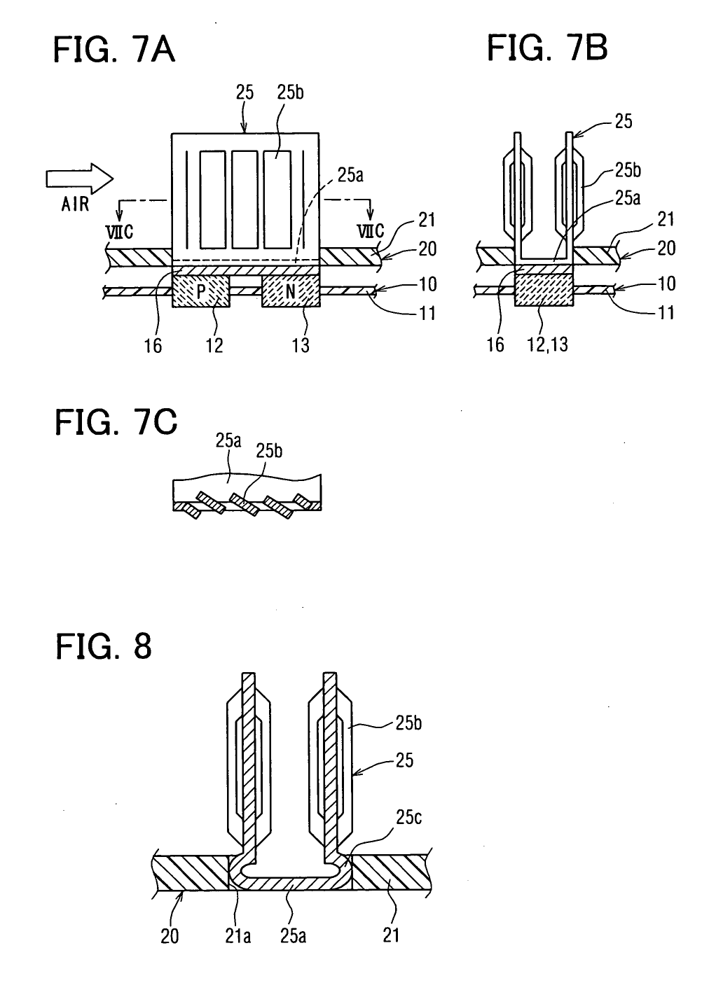

Each of the heat exchanging members 25 is formed of a thin plate of conductive material such as copper, and is formed nearly in the shape of a letter U in cross section as shown in FIGS. 7A-7C. Each of the heat exchanging members 25 has an electrode portion 25a formed in the shape of a plane at the bottom, and a heat exchanging portion (fin) 25b which is formed in the shape of a louver at a portion extended outward from the electrode portion 25a. The fin 25b is disposed for absorbing and radiating heat transmitted from the electrode portion 25a and is formed integrally with the electrode portion 25a by cutting and raising the thin plate.

In this embodiment, a plurality of heat exchanging members 25 are integrated with the second holding plate 21 such that the electrode portions 25a are arranged at predetermined positions corresponding to the arrangement of the electrode members 16 that are arranged in the thermoelectric device assembly 15. Furthermore, insertion holes 21a are provided in the second holding plate 21 so that the electrode portions 25a of the heat exchanging members 25 are inserted into the insertion holes 21a, respectively. In this embodiment, each of the insertion holes 21a is set to have an open area slightly smaller than a surface area of each electrode member 16, as an example, as shown in FIGS. 1 and 2.

When one end surface of each electrode portion 25a is bonded to one surface of each electrode member 16, an outer periphery of the insertion hole 21a of the second holding plate 21 contacts an outer periphery of the electrode member 16. Accordingly, when the electrode portion 25a is connected with the electrode member 16, the electrode member 16 is pressed by the second holding plate 21. Therefore, it can prevent the electrode member 16 from being shifted before the electrode portion 25a of the heat exchanging member 25 and the electrode member 16 are bonded to each other. The electrode portion 25a of the heat exchanging member 25 is formed to be fitted with the insertion hole 21a of the second holding plate 21.

For example, the electrode portion 25a is fitted with the insertion hole 21a such that one end surface of the electrode portion 25a slightly protrudes from one surface of the second holding plate 21. Furthermore, the heat exchanging member 25 is arranged such that the electrode portion 25a and the fin 25b are extended along the flow of air as shown in FIGS. 7A and 7B.

In this embodiment, the heat exchanging members 25 arranged on the one surface side (refer to FIG. 1) of the thermoelectric device substrate 10 are different in the direction of arrangement between a case where the heat exchanging members 25 are arranged at the outside end of the group of thermoelectric devices and a case where the heat exchanging members 25 are arranged at the inside of the outside end of the group of thermoelectric devices. In contrast, the heat exchanging members 25 arranged on the other surface side (refer to FIG. 2) of the thermoelectric device substrate 10 are set at the same in the direction of arrangement between a case where the heat exchanging members 25 are arranged at the outside end of the group of thermoelectric devices and a case where the heat exchanging members 25 are arranged at the inside of the outside end of the group of thermoelectric devices.

DC power inputted from the terminal 24a, as shown in FIG. 4, flows from the right upper electrode member 16 to the N-type thermoelectric device 13 and then flows in series through the adjacent P-type thermoelectric device 12 via the lower electrode member 16 and then flows from this P-type thermoelectric device 12 in series to the N-type thermoelectric device 13 via the upper electrode member 16. In other words, the electrode members 16 are connected to the thermoelectric devices 12, 13 in such a way that the DC power can flow in series to both ends of the thermoelectric devices 12, 13.

At this time, the upper electrode members 16 shown in FIG. 4 constructing the PN junctions are brought to a high temperature state by the Peltier effect and the lower electrode members 16 shown in FIG. 5 constructing the NP junctions are brought to a low temperature state.

That is, as shown in FIG. 3, air-flowing passages are formed on both sides of the thermoelectric device substrate 10 by the case member 28 and the thermoelectric device substrate 10 used as a partition wall. When air flows through the air-flowing passages, heat is exchanged between the fins 25b and air, thereby air can be heated by the upper fins 25b and can be cooled by the lower fins 25b by means of the partition wall of the thermoelectric device substrate 10.

In this embodiment, the positive terminal of the DC power source is connected to the terminal 24a and the negative terminal of the DC power source is connected to the terminal 24b to apply the DC power to the terminal 24a. However, the positive terminal of the DC power source may be connected to the terminal 24b and the negative terminal of the DC power source may be connected to the terminal 24a to apply the DC power to the terminal 24b. However, at this time, the upper heat exchanging members 25 construct the heat absorbing portions and the lower heat exchanging members 25 constructs the heat radiating portions.

Further, the second holding plate 21 is positioned adjacent to bonding portions between the electrode members 16 and the thermoelectric devices 12, 13, as shown in FIGS. 7A and 7B. Therefore, a heat transmitting amount from the side of the thermoelectric devices 12, 13 to the electrode members 16 and electrode portions 25a due to convention flow can be reduced. As a result, a heat transmitting amount through the bonding portions between the electrode members 16 and the thermoelectric devices 12, 13 is not reduced due to the second holding plate 21, thereby improving the thermoelectric conversion efficiency.

Because a thermal insulation space is provided between the one surface of the second holding plate 21 and the first holding plate 11, it can effectively restrict heat generated from the thermoelectric devices 12, 13 from bypassing the heat exchanging member 25.

In this embodiment, each of the insertion holes 21a formed in the second holding plate 21 has the open area slightly smaller than the surface area of the electrode member 16 connectable to the electrode portion 25a. That is, each insertion hole 21a having the rectangular shape is made slightly shorter in both the major side and the minor side of the rectangular shape, as compared with the electrode member 16. However, any one of the major side and the minor side of the rectangular shaped insertion hole 12 can be made slightly smaller than the flat surface area of the electrode member 16.

Next, a method for assembling a thermoelectric transducer will be described. First, a plurality of P-type thermoelectric devices 12 and a plurality of N-type thermoelectric devices 13 are formed and arranged alternately in a lattice pattern in holes formed in the first holding plate 11, to form the thermoelectric device substrate 10 having the thermoelectric devices 12, 13 integrally mounted on the first holding plate 11.

Then, a plurality of electrode members 16 each formed in the shape of a plane are located on the end surfaces of the thermoelectric devices 12, 13 arranged adjacently to the thermoelectric device substrate 10, as shown in FIG. 6. Then, the electrode members 16 are soldered to the thermoelectric devices 12, 13, so that the electrode device assembly 15 is formed.

For example, the electrode members 16 arranged on the upper side of the first holding plate 11 in FIG. 6 form PN junctions to electrically connect adjacent thermoelectric devices 12, 13 in series, and the electrode members 16 arranged on the lower side of the first holding plate 11 in FIG. 6 form NP junctions to electrically connect adjacent thermoelectric devices 12, 13 in series. The thermoelectric device substrate 10 may be manufactured by the use of a mounter of a manufacturing apparatus for mounting semiconductors and electronic components on a control substrate.

The electrode portions 25a of the heat exchanging members 25 are fitted with the insertion holes 21a of the second holding plates 21 to form a temporarily fixing state of the heat absorbing/radiating substrate 20. In this embodiment, the heat exchanging members 25 are arranged on the one side and the other side of the thermoelectric device substrate 10 to have different shapes in accordance with the arrangements of the plurality group of the thermoelectric devices 12, 13 shown in FIGS. 1 and 2. That is, a pair of heat absorbing/radiating substrate 20 on a heat radiating side and heat absorbing/radiating substrate 20 on a heat absorbing side are formed, so that the electrode device assembly 15 is sandwiched between and combined with the heat absorbing/radiating substrate 20 on the heat radiating side and the heat absorbing/radiating substrate 20 on the heat absorbing side. The respective electrode devices 16 are made to abut against and soldered together to the respective electrode portions 25a.

Accordingly, it can prevent a shift of the electrode members 16 which are connected to the thermoelectric devices 12, 13 in a predetermined arrangement corresponding to the arrangement of the thermoelectric devices 12, 13. Furthermore, because the plural heat exchanging members 25 are temporarily fixed before the bonding, the plural heat exchanging members 25 can be set at predetermined positions without a position shift.

Then, the case members 28 are combined with the second holding plate 21 to form air passages on the upper side and the lower side, thereby the heat radiating part and the heat absorbing part are formed on the upper side and the lower side of the thermoelectric device substrate 10. By flowing air through these heat radiating and absorbing parts, cold air and hot air can be obtained. The thermoelectric transducer like this can be applied to an apparatus for cooling a heat generating component such as semiconductor and electric component and for heating of a heating unit.

In the thermoelectric transducer according to the above-described embodiment, in the arrangement state where the thermoelectric device assembly 15 is inserted between the heat absorbing/radiating substrates 20, the outer peripheries of the electrode members 16 are set to contact the one surface of the second holding plate 21. That is, when the heat exchanging members 25 are bonded to the electrode members 16, the outer peripheries of the electrode members 16 contact the outer peripheries of the insertion holes 21a of the second holding plate 21. Therefore, the electrode members 16, which are arranged to correspond to the arrangements of the thermoelectric devices 12, 13, can be accurately connected with the heat exchanging members 25, without a position shift. Accordingly, the plural heat exchanging members 25 can be accurately assembled at predetermined positions corresponding to the arrangement state of the plural electrode members 16.

Furthermore, because the second holding plate 21 is located at a position adjacent to the bonding portion where the electrode members 16 are bonded to the thermoelectric devices 12, 13, an exposed surface area of the electrode members 16 exposed to an outside relative to the thermoelectric devices 12, 13 can be reduced. Therefore, a heat leakage amount from the thermoelectric devices 12, 13 due to convection can be reduced, thereby increasing a heat transmission amount from the thermoelectric devices 12, 13 to the heat exchanging member 25 through the electrode members 16. As a result, the converting efficiency of the thermoelectric transducer can be effectively improved.

Because the heat insulation space is formed between the second holding plate 21 and the first holding plate 11, it can restrict heat generated from the thermoelectric devices 12, 13 from being leaked to the heat exchanging areas of the heat exchanging members 25 without passing through the electrode members 16.

In the pair of the heat absorbing/radiating substrates 20 located at both sides of the thermoelectric device assembly 15, after the electrode portions 25a of the heat exchanging members 25 are temporarily fixed to the peripheries of the insertion holes 21a of the second holding plates 21, all the electrode portions 25a are bonded to the electrode members 16 together. Therefore, the heat exchanging members 25 can be bonded with the electrode members 16 at predetermined positions without a position shift before the bonding. Because the bonding of the electrode portions 25 and the electrode members 16 is performed together, manufacturing steps for forming the thermoelectric transducer can be reduced.

Furthermore, each of the insertion holes 21 is opened in the second holding plate 21 with the open area that is slightly smaller than the surface area of the electrode member 16. Therefore, the outer periphery of the insertion hole 21a of the second holding plate 21 can be made to contact the outer periphery of the electrode member 16. Accordingly, a position shift of the electrode members 16, arranged in a predetermined arrangement corresponding to the arrangement state of the thermoelectric devices 12, 13, can be prevented.

In this embodiment, after the electrode portions 25a of the heat exchanging members 25 are temporarily fixed to the second holding plate 21 via the insertion holes 21a in each heat absorbing/radiating substrate 20, the electrode portions 25a of a pair of the heat absorbing/radiating substrates 20 are bonded with the electrode members 16 of the thermoelectric device assembly 15. Furthermore, in the state where the thermoelectric device assembly 15 is located between the heat absorbing/radiating substrates 20, the outer peripheries of the electrode members 16 contact the one surface of the second holding plate 21, and the heat exchanging members 25 and the electrode members 16 are bonded integrally by soldering.

Because the outer peripheries of the electrode members 16 are made to contact the one surface of the second holding plate 21, it can effectively prevent a position shift of the electrode members 16 before the bonding.

### Other Embodiments

Although the present invention has been fully described in connection with the preferred embodiments thereof with reference to the accompanying drawings, it is to be noted that various changes and modifications will become apparent to those skilled in the art.

For example, in the above-described embodiment, the electrode portions 25a of the heat exchanging members 25 are fitted with the insertion holes 21a of the second holding plate 21 so as to be temporarily fixed to the second holding plate 21. However, the electrode portions 25a of the heat exchanging members 25 can be press-inserted into the insertion holes 21a of the second holding plate 21 so as to be temporarily fixed to the second holding plate 21.

Furthermore, as shown in FIG. 8, the press-inserting portion of the heat exchanging member 25 can be formed to have curved roof portion 25c having an elasticity. In this case, the electrode portion 25a can be easily press-inserted into the insertion holes 21a. Alternatively, the electrode portion 25a of the heat exchanging member 25 can be fixed into the insertion hole 21a by using an adhesive after being inserted into the insertion hole 21a.

In the above-described embodiment, the fin 25b of the heat exchanging member 25 is formed into a louver shape, however, can be formed into other shape such as an offset shape.

In the above-described embodiment, each of the insertion hole 21a is formed substantially into a rectangular shape. However, the open shape of the insertion hole 21a can be suitably changed in accordance with the shape of the electrode portion 25a of the heat exchanging member 25 or/and the shape of the electrode member 16. Furthermore, the surface shape of the electrode device 16 connected with the electrode portion 25a of the heat exchanging member 25 can be suitably changed in accordance with the shape of the heat exchanging member 25.

Such changes and modifications are to be understood as being within the scope of the present invention as defined by the appended claims.

What is claimed is:

1. A thermoelectric transducer comprising:
a thermoelectric device assembly that includes a plurality of P-type thermoelectric devices, a plurality of N-type thermoelectric devices, a first holding plate for holding the plurality of P-type thermoelectric devices and N-type thermoelectric devices, and a plurality of electrode members for electrically connecting the plurality of P-type thermoelectric devices and N-type thermoelectric devices in series, wherein the plurality of electrode members are arranged in a predetermined arrangement corresponding to an arrangement of the plurality of P-type thermoelectric devices and N-type thermoelectric devices; and
a pair of heat exchanging member assemblies each of which includes a plurality of heat exchanging members provided in correspondence with the plurality of electrode members, and a second holding plate for holding the plurality of heat exchanging members, the plurality of heat exchanging members being held in an arrangement corresponding to the predetermined arrangement of the electrode members, wherein:
the thermoelectric device assembly is located between the pair of heat exchanging member assemblies; and
each of the plurality of electrode members has an outer periphery that contacts one surface of the second holding plate in a state where the electrode member is connected to the heat exchanging member.

2. The thermoelectric transducer according to claim 1, wherein:
the heat exchanging members have electrode portions connectable respectively to the electrode members of the thermoelectric device assembly to transmit heat, and heat exchanging portions for exchanging heat transmitted from the electrode portions; and
the second holding plate has a plurality of insertion holes into which the electrode portions of the heat exchanging members are inserted, respectively.

3. The thermoelectric transducer according to claim 2, wherein each of the insertion holes has an open area that is smaller than a surface area of each electrode member connected to the electrode portion of each heat exchanging member.

4. The thermoelectric transducer according to claim 2, wherein the electrode portion of each heat exchanging member is press-inserted into the insertion hole of the second holding plate.

5. The thermoelectric transducer according to claim 2, wherein the electrode portion of each heat exchanging member is fitted with the insertion hole of the second holding plate.

6. The thermoelectric transducer according to claim 2, wherein the electrode members are connected to the electrode portions of the heat exchanging members in a state where the outer periphery of each electrode member contacts the one surface of the second holding plate at a peripheral portion of the insertion hole.

7. The thermoelectric transducer according to claim 2, wherein:
each of the insertion holes has substantially a rectangular shape having a major dimension and a minor dimension, and each of the electrode members has substantially a rectangular shape having a major dimension and a minor dimension; and
one of the major dimension and the minor dimension of the rectangular-shaped electrode member is larger than corresponding one of the major dimension and the minor dimension of the insertion hole.

8. The thermoelectric transducer according to claim 1, wherein the second holding plate is separate from the first holding plate by a space.

9. The thermoelectric transducer according to claim 1, wherein the second holding plate is located adjacent to connection positions where the electrode members are connected to the thermoelectric devices.

10. A method of manufacturing a thermoelectric transducer, comprising the step of:
forming a plurality of P-type thermoelectric devices and a plurality of N-type thermoelectric devices;
arranging the plurality of P-type thermoelectric devices and the plurality of N-type thermoelectric devices in a predetermined arrangement to be held by a first holding plate;
electrically connecting the plurality of P-type thermoelectric devices and plurality of N-type thermoelectric devices in series by using a plurality of electrode members so as to form a thermoelectric device assembly, wherein the plurality of electrode members are arranged in a predetermined arrangement corresponding to an arrangement of the plurality of P-type thermoelectric devices and N-type thermoelectric devices;
forming a plurality of heat exchanging members;
holding the plurality of heat exchanging members by a second holding plate, wherein the plurality of heat exchanging members are held by the second holding plate in an arrangement corresponding to the predetermined arrangement of the electrode members so as to form a heat exchanging member assembly;
temporarily fixing the thermoelectric device assembly between a pair of the heat exchanging member assemblies such that an outer periphery of each electrode member contacts one surface of the second holding plate; and
bonding together the electrode members to the respective heat exchanging members in a contact state where the outer periphery of each electrode member contacts the one surface of the second holding plate.

11. The method according to claim 10, wherein
in the step of forming the plurality of heat exchanging members, each of the heat exchanging members is formed to have an electrode portion connectable to the electrode member and a heat exchanging portion for exchanging heat transmitted from the electrode portion, the method further comprising:
forming a plurality of insertion holes in the second holding plate at positions corresponding to the arrangement of the electrode members such that each of the insertion holes has an open area that is smaller than a surface area of each electrode members.

12. The method according to claim 11, further comprising
fitting the electrode portions of the heat exchanging members with the insertion holes of the second holding plate, respectively, to temporarily fix the heat exchanging members.

13. The method according to claim 11, further comprising
press-inserting the electrode portions of the heat exchanging members into the insertion holes of the second holding plate, respectively, to temporarily fix the heat exchanging members.

14. The method according to claim 11, wherein the electrode members are bonded to the electrode portions of the heat exchanging members together in the contact state.
